(19) United States
(12) Patent Application Publication
(10) Pub. No.: US 2002/0125524 A1
(43) Pub. Date: Sep. 12, 2002

(54) Semiconductor device and method of manufacturing same

(75) Inventors: Tomonori Okudaira, Tokyo (JP); Yoshikazu Tsunemine, Tokyo (JP); Keiichiro Kashihara, Tokyo (JP); Akie Yutani, Tokyo (JP); Hiromi Itoh, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MITSUBISHI DENKI KABUSHIKI KAISHA, Tokyo (JP)

(21) Appl. No.: 10/143,021

(22) Filed: May 13, 2002

Related U.S. Application Data
(62) Division of application No. 09/631,620, filed on Aug. 4, 2000.

(30) Foreign Application Priority Data
Feb. 3, 2000 (JP) P2000-025866

(51) Int. Cl. H01L 27/108

(52) U.S. Cl. 257/310

(57) ABSTRACT

A semiconductor device having a stacked capacitor is provided. A dielectric film (81) formed of BST by a sputtering process is entirely provided to cover upper part of a plurality of storage node electrodes (SN2). A dielectric film (82) formed of BST by a CVD process is entirely provided to cover the dielectric film (81). The dielectric films (81, 82) constitute a dielectric layer (80). A conductive layer made of platinum covers an entire surface of the dielectric film (82) to constitute a counter electrode (9) to the storage node electrodes. The dielectric layer has good step coverage, reduced dependence upon its underlying layer, and good crystallinity.

### BACKGROUND OF THE INVENTION

1. Field of the Invention

The present invention relates to a semiconductor device and a method of manufacturing the same. More particularly, the invention relates to a semiconductor device including a stacked capacitor and a method of manufacturing the same.

2. Description of the Background Art

The increase in integration density of semiconductor devices often results in serious problems which have not appeared with conventional low-integration semiconductor devices. Description will be given on such problems, taking a DRAM (dynamic random access memory) as an example.

FIG. 11 shows a cross-sectional structure of a memory cell portion of a DRAM having stacked capacitors SC1 as an example of conventional relatively low-integration DRAMs.

Referring to FIG. 11, an interlayer insulation film 55 is formed on a silicon substrate 1, and a plurality of conductive plugs 56 are provided which extend through the interlayer insulation film 55 to reach the silicon substrate 1. Although the plugs 56 are connected to doped layers such as source/drain layers provided in a surface of the silicon substrate 1, the doped layers are not shown in FIG. 11.

Each of the plugs 56 has a first end connected to a barrier metal layer 573 selectively provided on the interlayer insulation film 55, and a bottom electrode 572 made of platinum is provided on a main surface of the barrier metal layer 573. Sidewall spacers 571 cover the side surfaces of the barrier metal layer 573 and the bottom electrode 572. The barrier metal layer 573, the bottom electrode 572 and the sidewall spacers 571 constitute a storage node electrode SN1 of a stacked capacitor.

The storage node electrode SN1 is provided on each of the plugs 56. A dielectric film 58 made of BST (barium strontium titanate) or the like is entirely provided to cover upper part of the plurality of storage node electrodes SN1. A counter electrode (referred to as a cell plate) 59 to the storage node electrodes SN1 is entirely provided to cover the dielectric film 58. The stacked capacitors SC1 are thus constructed.

When the degree of integration is low as shown in FIG. 11, the storage node electrodes SN1 are low in height, and the dielectric film 58 has good step coverage if the dielectric film 58 is formed using a sputtering process. However, the increase in degree of integration increases the height of the storage node electrodes SN1 to cause the step coverage of the dielectric film 58 to become a problem.

FIG. 12 shows a cross-sectional structure of a memory cell portion of a DRAM having stacked capacitors SC2 as an example of conventional relatively high-integration DRAMs.

Referring to FIG. 12, an interlayer insulation film 5 is formed on the silicon substrate 1, and a plurality of conductive plugs 6 are provided which extend through the interlayer insulation film 5 to reach the silicon substrate 1. Although the plugs 6 are connected to doped layers such as source/drain layers provided in a surface of the silicon substrate 1, the doped layers are not shown in FIG. 12.

Each of the plugs 6 has a first end connected to a barrier metal layer 71 selectively provided on the interlayer insulation film 5, and a bottom electrode 72 made of platinum is provided on a main surface of the barrier metal layer 71. Sidewall electrodes 73 cover the side surfaces of the barrier metal layer 71 and the bottom electrode 72. The barrier metal layer 71, the bottom electrode 72 and the sidewall electrodes 73 constitute a storage node electrode SN2 of a stacked capacitor.

The storage node electrode SN2 is provided on each of the plugs 6. A dielectric film 8 made of BST or the like is entirely provided to cover upper part of the plurality of storage node electrodes SN2. A counter electrode (referred to as a cell plate) 9 to the storage node electrodes SN2 is entirely provided to cover the dielectric film 8. The stacked capacitors SC2 are thus constructed.

A problem encountered in this case is the step coverage of the dielectric film 8 constituting a dielectric layer of the capacitors.

The sputtering process is a process for causing atoms or ions to collide with a material (referred to hereinafter as a target material) of a film to be formed, thereby to achieve film deposition using the atoms or molecules of the sputtered target material. Since the atoms of the target material has energy during film formation and sputtering employs a plasma of noble gas in a vacuum chamber, the sputtering process is advantageous in forming a film containing a small amount of impurity and in ease of crystallization. On the other hand, the sputtering process is disadvantageous in step coverage characteristic. It is difficult to form the dielectric film 8 uniformly on the side surface of the storage node electrodes SN2 having an increased height because of the increase in integration density as shown in FIG. 12, and the dielectric film 8 sometimes has a discontinuous broken form. The nonuniform thickness of the dielectric layer or the presence of a discontinuous part thereof causes variations in capacitance and, in some cases, provides defective capacitors.

A CVD (chemical vapor deposition) process is considered to be a process for forming a film having good step coverage. The CVD process utilizes a chemical reaction to produce a metal oxide from an organic compound of metal. Therefore, film formation conditions differ between a film to be formed on an underlying layer made of a highly chemically reactive material such as platinum and a film to be formed on an underlying layer made of a chemically inert material such as silicon oxide. This presents difficulties in uniform film deposition.

For example, the stacked capacitors SC2 shown in FIG. 12, in which the storage node electrodes SN1 are generally made of platinum and the interlayer insulation film 5 is made of silicon oxide, meet the above-mentioned conditions.

The dielectric film 8 must have a high dielectric constant, and therefore crystallization is essential therefor. However, the CVD process which basically uses only heat energy for film deposition is inferior in crystallinity to the sputtering process in principle. Additionally, in the CVD process, carbonates and moisture generated during the burning process of raw materials are contained in the film to become a factor that hinders crystallization.

### SUMMARY OF THE INVENTION

According to a first aspect of the present invention, a semiconductor device comprises: an underlying layer; and a plurality of capacitors formed on the underlying layer, each of the plurality of capacitors including a lower electrode, a dielectric layer, and an upper electrode provided in opposed relation to the lower electrode with the dielectric layer therebetween, the dielectric layer including a first dielectric film provided to cover an upper part and a side surface of the lower electrode and an upper part of the underlying layer which lies between the plurality of capacitors, and a second dielectric film provided to cover an upper part and a side surface of the first dielectric film which overlies the lower electrode, and an upper part of the first dielectric film which lies between the plurality of capacitors, wherein the first and second dielectric films have a perovskite-type crystal structure, and have substantially the same lattice constant.

Preferably, according to a second aspect of the present invention, in the semiconductor device of the first aspect, the first dielectric film contains at least one of an ion at a face-centered position and an ion at a body-centered position of the perovskite-type crystal structure of the second dielectric film.

Preferably, according to a third aspect of the present invention, in the semiconductor device of the first aspect, the first dielectric film is formed by a physical deposition process; and the second dielectric film is formed by a chemical deposition process.

Preferably, according to a fourth aspect of the present invention, in the semiconductor device of the third aspect, the first dielectric film is formed by a sputtering process; and the second dielectric film is formed by a CVD process.

Preferably, according to a fifth aspect of the present invention, in the semiconductor device of the third aspect, the dielectric layer further includes a third dielectric film provided to cover an upper part and a side surface of the second dielectric film which overlies the lower electrode, and an upper part of the second dielectric film which lies between the plurality of capacitors.

Preferably, according to a sixth aspect of the present invention, in the semiconductor device of the fifth aspect, the third dielectric film is formed by a physical deposition process.

A seventh aspect of the present invention is intended for a method of manufacturing a semiconductor device including a plurality of capacitors formed on an underlying layer, each of the plurality of capacitors including a lower electrode, a dielectric layer, and an upper electrode provided in opposed relation to the lower electrode with the dielectric layer therebetween. According to the present invention, the method comprises the step of forming the dielectric layer, the step of forming the dielectric layer including the steps of: (a) forming a first dielectric film by a physical deposition process to cover an upper part and a side surface of the lower electrode and an upper part of the underlying layer which lies between the plurality of capacitors, and (b) forming a second dielectric film by a chemical deposition process by using a crystal of the first dielectric film as a seed to cover an upper part and a side surface of the first dielectric film which overlies the lower electrode, and an upper part of the first dielectric film which lies between the plurality of capacitors, wherein the first and second dielectric films have a perovskite-type crystal structure, and have substantially the same lattice constant.

Preferably, according to an eighth aspect of the present invention, in the method of the seventh aspect, the step (a) comprises the step of forming the first dielectric film by a sputtering process; and the step (b) comprises the step of forming the second dielectric film by a CVD process.

Preferably, according to a ninth aspect of the present invention, in the method of the seventh aspect, the step of forming the dielectric layer further includes the step of (c) forming a third dielectric film by a physical deposition process to cover an upper part and a side surface of the second dielectric film which overlies the lower electrode, and an upper part of the second dielectric film which lies between the plurality of capacitors, the step (c) being performed after the step (b).

In the semiconductor device of the first aspect of the present invention, the second dielectric film is provided to cover the upper part and the side surface of the first dielectric film which overlies the lower electrode, and the upper part of the first dielectric film which lies between the plurality of capacitors. Thus, if the first dielectric film on the upper part and side surface of the lower electrode has a non-uniform thickness, the entire dielectric layer has a uniform thickness, whereby variations in capacitance are suppressed. Further, the first and second dielectric films have the respective perovskite-type crystal structures which are approximately the same in at least lattice constant. Thus, the first and second dielectric films provide a small crystal lattice misfit. This allows the use of a process for crystal growth of the second dielectric film using the crystal of the first dielectric film as a seed, to provide the semiconductor device comprising the dielectric layer having good crystallinity.

In the semiconductor device of the second aspect of the present invention, the first dielectric film contains at least one of the ion at the face-centered position and the ion at the body-centered position of the perovskite-type crystal structure of the second dielectric film. This reduces the crystal lattice misfit in the case of the crystal growth of the second dielectric film using the crystal of the first dielectric film as a seed, to provide the semiconductor device comprising the dielectric layer having good crystallinity.

In the semiconductor device of the third aspect of the present invention, the first dielectric film which is formed by the physical deposition process is a dielectric film containing a small amount of impurity and having good crystallinity, and allows the crystal growth of the second dielectric film using the crystal of the first dielectric film as a seed. Additionally, if a highly chemically reactive material is contained in the underlying layer, the first dielectric film deposited by physical reaction does not overreact therewith, and does not present the problem of the dependence upon the underlying layer. Further, the second dielectric film which is formed by the chemical deposition process is a dielectric film having good step coverage. Therefore, the dielectric layer having a uniform thickness is provided even if the height of the lower electrode is increased for the increase in degree of integration of the semiconductor device.

In the semiconductor device of the fourth aspect of the present invention, the first and second dielectric films formed by the sputtering process and the CVD process respectively are used. Thus, the first dielectric film is a dielectric film containing a small amount of impurity and having good crystallinity, and the second dielectric film is a film resulting from the crystal growth using the crystal of the first dielectric film as a seed. Both of the first and second dielectric films constitute the dielectric layer having good crystallinity.

In the semiconductor device of the fifth aspect of the present invention, when the second dielectric film is formed by the chemical deposition process and contains impurities and the like, the formation of the third dielectric film having good film quality causes the upper electrode to provide an interface with the upper surface of the third dielectric film. This provides the semiconductor device which is reduced in crystal defects at the interface and in dielectric loss.

The semiconductor device of the sixth aspect of the present invention comprises the third dielectric film having good film quality.

In the method of the seventh aspect of the present invention, the first dielectric film which is formed by the physical deposition process is a dielectric film containing a small amount of impurity and having good crystallinity, and the second dielectric film is a dielectric film having good crystallinity because of the crystal growth of the second dielectric film using the crystal of the first dielectric film as a seed. Additionally, if a highly chemically reactive material is contained in the underlying layer, the first dielectric film deposited by physical reaction does not overreact therewith, and does not present the problem of the dependence upon the underlying layer. Further, the second dielectric film which is formed by the chemical deposition process is a dielectric film having good step coverage. Therefore, the dielectric layer having a uniform thickness is provided even if the height of the lower electrode is increased for the increase in degree of integration of the semiconductor device.

In the method of the eighth aspect of the present invention, the sputtering process and the CVD process which are technically established are used to form the first and second dielectric films, respectively. Therefore, the first and second dielectric films are formed reliably with high productivity, and the reductions in reliability and yield resulting from the provision of the first and second dielectric films are suppressed.

In the method of the ninth aspect of the present invention, when the second dielectric film is formed by the chemical deposition process and contains impurities and the like, the formation of the third dielectric film on the second dielectric film by the physical deposition process causes the upper electrode to provide an interface with the upper surface of the third dielectric film having good film quality. This provides the semiconductor device which is reduced in crystal defects at the interface and in dielectric loss.

It is therefore an object of the present invention to provide a semiconductor device which comprises a stacked capacitor, and a dielectric layer having good step coverage, reduced dependence upon its underlying layer, and good crystallinity.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 illustrates a structure of a semiconductor device according to a first preferred embodiment of the present invention;

FIGS. 2 through 7 illustrate manufacturing steps of the semiconductor device according to the first preferred embodiment of the present invention;

FIG. 8 illustrates a structure of the semiconductor device according to a second preferred embodiment of the present invention;

FIGS. 9 and 10 illustrate manufacturing steps of the semiconductor device according to the second preferred embodiment of the present invention; and

FIGS. 11 and 12 illustrate structures of background art semiconductor devices.

### DESCRIPTION OF THE PREFERRED EMBODIMENTS

<A. First Preferred Embodiment>

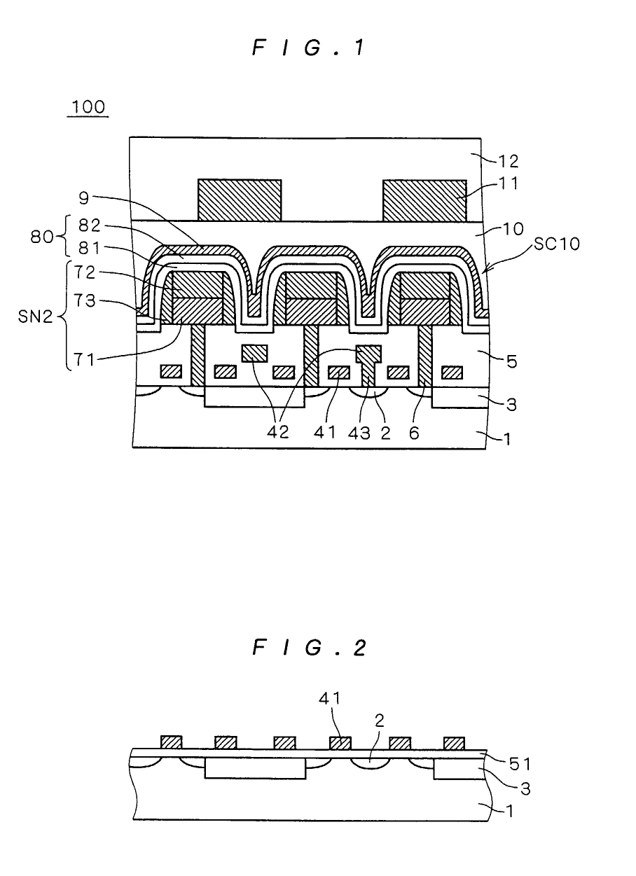

FIG. 1 shows a cross-sectional structure of a memory cell portion of a DRAM 100 according to a first preferred embodiment of the present invention.

<A-1. Device Construction>

With reference to FIG. 1, an interlayer insulation film 5 is formed on a silicon substrate, and a plurality of conductive plugs 6 are provided which extend through the interlayer insulation film 5 to reach the silicon substrate 1. The plugs 6 are made of polysilicon or titanium nitride (TiN).

A plurality of source/drain layers 2 of MOS transistors and a plurality of isolating insulation films 3 for electrically isolating the MOS transistors from each other are formed in a surface of the silicon substrate 1. The plugs 6 are connected to some of the source/drain layers 2, respectively.

In the interlayer insulation film 5, gate electrodes 41 are provided correspondingly over parts of the silicon substrate 1 which lie between adjacent ones of the source/drain layers 2, and a bit line 42 is provided correspondingly over one of the source/drain layers 2 which is not connected to the plugs 6. A bit line contact 43 for establishing electric connection between the bit line 42 and the corresponding source/drain layer 2 is provided therebetween.

Other gate electrodes 41 serving as a transfer gate are provided also over the isolating insulation films 3, and another bit line 42 is provided also over one of the isolating insulation films 3.

Each of the plugs 6 has a first end connected to a barrier metal layer 71 selectively provided on the interlayer insulation film 5, and a bottom electrode 72 made of platinum is provided on a main surface of the barrier metal layer 71. Sidewall electrodes 73 made of platinum are provided to cover the side surfaces of the barrier metal layer 71 and the bottom electrode 72. The barrier metal layer 71, the bottom electrode 72 and the sidewall electrodes 73 constitute a storage node electrode SN2 (a lower electrode) of a stacked capacitor.

The storage node electrode SN2 is provided on each of the plugs 6. A dielectric film 81 (a first dielectric film) formed of BST by a sputtering process is entirely provided to cover upper part of the plurality of storage node electrodes SN2.

A dielectric film 82 formed of BST by a CVD process is entirely provided to cover the dielectric film 81. The dielectric films 81 and 82 constitute a dielectric layer 80.

A conductive layer made of platinum is entirely provided to cover the dielectric film 82 (a second dielectric film), constituting a counter electrode (referred to as a cell plate) 9 (an upper electrode) to the storage node electrodes SN2.

Each of the storage node electrodes SN2, the dielectric films 81 and 82, and the cell plate 9 constitute a stacked capacitor SC10.

An interlayer insulation film 10 covers the stacked capacitors SC10, and a metal interconnect layer 11 is provided on the interlayer insulation film 10. A passivation film 12 covers the metal interconnect layer 11. The DRAM 100 is thus constructed.

<A-2. Manufacturing Method>

A method of manufacturing the DRAM 100 will be discussed with reference to FIGS. 2 through 7.

First, in the step shown in FIG. 2, the silicon substrate 1 is prepared, and the isolating insulation films 3 made of an oxide are selectively formed in the surface of the silicon substrate 1.

Next, an oxide film 51 serving as a gate oxide film is formed entirely on top of a resultant structure, and the gate electrodes 41 are selectively formed on the oxide film 51. In this step, some of the gate electrodes 41 are formed over the isolating insulation films 3 to serve as transfer gates (word lines).

Using the gate electrodes 41 as a mask, impurity ions are implanted into parts of the silicon substrate 1 which immediately underlie the oxide film 51 to selectively form the source/drain layers 2.

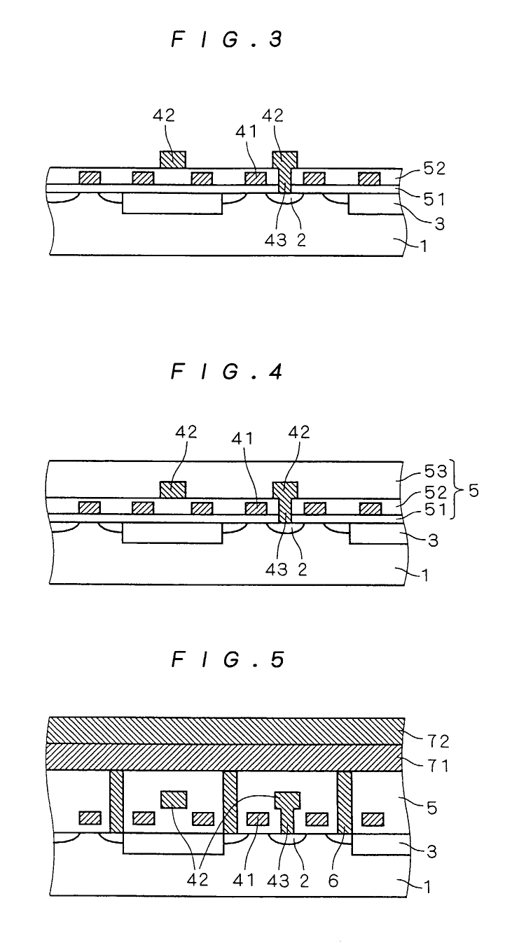

Next, in the step shown in FIG. 3, an interlayer insulation film 52 made of an oxide is formed to completely cover the gate electrodes 41. A contact hole is selectively formed which extends through the interlayer insulation film 52 and the oxide film 51 to reach one of the source/drain layer 2, and is then filled with a conductor to form the bit line contact 43.

Then, one of the bit lines 42 is formed on the bit line contact 43, whereby electric connection is established between the bit line 42 and its corresponding source/drain layer 2. The other bit line 42 is formed over one of the isolating insulation films 3.

Next, in the step shown in FIG. 4, an interlayer insulation film 53 made of an oxide is formed to completely cover the bit lines 42. The oxide film 51, and the interlayer insulation films 52, 53 are generically referred to as the interlayer insulation film 5. This term “interlayer insulation film 5” will be used for description hereinafter.

Next, in the step shown in FIG. 5, contact holes extending through the interlayer insulation film 5 to reach some of the source/drain layers 2 which are not connected to the bit line contact 43 are formed by a conventional dry etching process. Thereafter, a conductor, e.g. a doped polysilicon layer, is formed on the interlayer insulation film 5 so as to fill the contact holes. Only part of the doped polysilicon layer which lies on the interlayer insulation film 5 is removed by etchback so that the plugs 6 are formed. The thickness of the part of the doped polysilicon layer which lies on the interlayer insulation film 5 is about 1.5 times the opening radius of the contact holes.

The conductor which forms the plugs 6 is not limited to the doped polysilicon but may be metal such as tungsten (W) or a conductive nitride such as TiN. The etchback process may employ a CMP (chemical mechanical polishing) technique.

Subsequently, the barrier metal layer 71 made of, e.g., TiN is formed on the plugs 6 by a sputtering process, and the bottom electrode 72 made of platinum is formed on the barrier metal layer 71 by a sputtering process.

The thickness of the barrier metal layer 71 ranges from 50 to 200 nm, and the thickness of the bottom electrode 72 ranges from 10 to 100 nm.

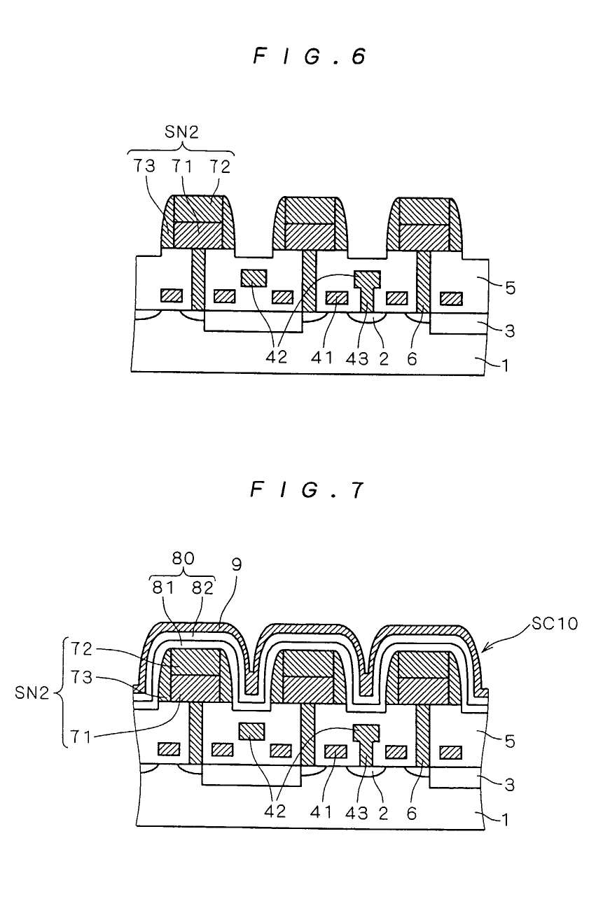

Next, in the step shown in FIG. 6, the barrier metal layer 71 and the bottom electrode 72 are patterned into a predetermined pattern by a dry etching process. Thereafter, a platinum layer having a thickness of about 50 nm is formed by a sputtering process to entirely cover the barrier metal layers 71 and the bottom electrodes 72.

The platinum layer is removed by anisotropic etching to form the sidewall electrodes 73 on the side surfaces of the barrier metal layers 71 and the bottom electrodes 72. This provides the storage node electrodes SN2.

In some cases, an insulator may be used in place of the bottom electrodes 72.

Additionally, each of the storage node electrodes SN2 may have a single-layer structure comprised of a thick layer of ruthenium (Ru) in place of the two-layer structure comprised of the barrier metal layer 71 and the bottom electrode 72.

Next, in the step shown in FIG. 7, a BST film is formed by a sputtering process to cover the storage node electrodes SN2, thereby forming the dielectric film 81.

The dielectric film 81 is formed under the following conditions: A technique of sputtering a target material using ions or atoms produced by a plasma generated by high-frequency discharge is used. The temperature of the silicon substrate 1 ranges from 200 to 600° C. Argon gas (Ar) and oxygen (O₂) at a 1:0 or 1:1 ratio are introduced into a deposition chamber. The pressure in the deposition chamber is about 0.1 Pa (pascal). High-frequency power for input to the target material is about 1 kW. The thickness of the dielectric film 81 ranges from 5 to 30 nm.

The target material used herein is BaSrTiO₃ which contains barium (Ba), strontium (Sr) and titanium (Ti) at a 1:1:2 ratio, although a Ba-to-Sr ratio is not limited thereto.

After the BST film is formed by sputtering, heat treatment for crystallization is performed to complete the dielectric film 81.

As described above, the sputtering process has the coverage characteristic problem. The BST film on the upper surface of the storage node electrodes SN2 (on the upper surface of the bottom electrodes 72) has a desired thickness, e.g. 20 nm, but on the side surface of the storage node electrodes SN2 (on the surface of the sidewall electrodes 73) has a thickness of 6 to 7 nm.

Then, a BST film is formed by a CVD process to entirely cover the dielectric film 81, thereby forming the dielectric film 82. The dielectric film 82 has a thickness ranging from 5 to 50 nm.

The dielectric film 82 is formed under the following conditions: The temperature of the silicon substrate 1 ranges from 350 to 500° C. The raw material used is a mixture of Ba(DPM)₂ and THF (tetrahydrofuran), a mixture of Sr(DPM)₂ and THF or a mixture of Ti(i-PrO)₂(DPM)₂ and THF. The pressure in the deposition chamber ranges from about 13.33 to about 1333 Pa (from about 0.1 to about 10 Torr).

In the above chemical formulas, DPM denotes C₁₁H₁₉O₂ (dipivaloyl methane), and (i-PrO)₂ denotes (O-i-C₃H₇)₂.

Then, a platinum layer is formed by a sputtering process to entirely cover the dielectric film 82, thereby forming the cell plate 9 (the upper electrode). The cell plate 9 has a thickness of about 60 nm.

Subsequently, the interlayer insulation film 10 is formed to completely cover the stacked capacitors SC10. Then, the metal interconnect layer 11 is formed on the interlayer insulation film 10, and the passivation film 12 is formed to cover the metal interconnect layer 11.

Finally, a hydrogen anneal is performed in an atmosphere of hydrogen at a temperature of 400° C. for 20 minutes to recover damages caused in the course of the manufacture. Thus, the DRAM 100 shown in FIG. 1 is completed.

The materials of the bottom electrodes 72, the sidewall electrodes 73 and the cell plate 9 are not limited to platinum, but may be other platinum-group elements (Ru, Rh, Pd, Os, Ir) or alloys of these elements.

<A-3. Function and Effect>

As described hereinabove, the total thickness of the dielectric film 81 and the dielectric film 82 formed thereon is, for example, 40 nm on the upper surface of the storage node electrodes SN2 (on the upper surface of the bottom electrodes 72), and 26 to 27 nm on the side surface of the storage node electrodes SN2 (on the surface of the sidewall electrodes 73).

If only the sputtering process is used to form the BST film having a thickness of 40 nm on the upper surface of the storage node electrodes SN2, the thickness of the BST film on the side surface of the storage node electrodes SN2 is 13 nm. The combined use of the sputter deposition and the CVD deposition improves the step coverage characteristics to provide a uniform dielectric layer, suppressing variations in capacitance.

The formation of the dielectric film 82 on the dielectric film 81 formed by the sputtering process eliminates the problem of the dependence of the dielectric layer upon its underlying layer which is encountered in the case of the CVD deposition.

Additionally, the dielectric film 81 formed by the sputtering process has good crystallinity, and the dielectric film 82 is epitaxially grown using a crystal of the dielectric film 81 as a seed. Therefore, the dielectric film 82 has better crystallinity than does a dielectric film deposited by the CVD process on a layer of platinum or silicon oxide.

For the epitaxial growth of the dielectric film 82 using the crystal of the dielectric film 81 as a seed, it is desirable that both of the dielectric films 81 and 82 are the same. More specifically, it is desirable that the dielectric films 81 and 82 have not only the same composition but also the same crystal structure and the same crystal lattice constant (referred to hereinafter as “lattice constant”). However, the minimum requirement is that the dielectric films 81 and 82 are the same in arrangement of A-site (face-centered position) ions or B-site (body-centered position) ions of a perovskite crystal.

For example, BST which is a solid solution of BaTiO₃ (abbreviated as “BT”) and SrTiO₃ (abbreviated as “ST”) has a lattice constant whose value ranges between the lattice constants of BT and ST in accordance with a Ba/Sr ratio.

The lattice constant of BT is 3.992 Å for the a-axis and 4.0361 Å for the c-axis. The lattice constant of ST is 3.905 Å for the a-axis and c-axis. The differences in lattice constant between BST and ST and between BST and BT are about 10% at the maximum. Thus, it can be said that BST, ST and BT are substantially the same in lattice constant.

Therefore, there are small BST-ST and BST-BT crystal lattice misfits. This allows crystal growth when forming a BST film by a CVD process on a BT film formed by a sputtering process or when forming a BST film by a CVD process on a ST film formed by a sputtering process.

The same considerations apply with respect to PZT. Specifically, PZT which is a solid solution of PbTiO₃ (abbreviated as “PT”) and PbZrO₃ (abbreviated as “PZ”) has a lattice constant whose value ranges between the lattice constants of PT and PZ in accordance with a Zr/Ti ratio.

The lattice constant of PT is 3.899 Å for the a-axis and 4.150 Å for the c-axis. The lattice constant of PZ is 4.15 Å for the a-axis and 4.11 Å for the c-axis. The differences in lattice constant between PZT and PT and between PZT and PZ are about 10% at the maximum. Thus, it can be said that PZT, PT and PZ are substantially the same in lattice constant.

Therefore, there are small PZT-PT and PZT-PZ crystal lattice misfits. This allows crystal growth when forming a PZT film by a CVD process on a PT film formed by a sputtering process or when forming a PZT film by a CVD process on a PZ film formed by a sputtering process.

<A-4. Modifications>

Although the BST film is used as the dielectric films 81 and 82 in the above description, the material of the dielectric films 81 and 82 is not limited to BST. For example, a PZT (lead zirconate titanate) film, a PLZT (a metal oxide formed by doping PZT with La) film, a Ta₂O₅ film, or a SBT (SrBi₂Ta₂O₉) film may be used as both of the dielectric films 81 and 82.

The conditions under which the above described films are formed by a sputtering process may be changed in accordance with the target material, and the conditions of plasma generation and the like for the formation of the above described films are similar to those for the formation of the BST film.

The PZT film is formed by a CVD process under the following conditions: The temperature of the silicon substrate 1 ranges from 300 to 600° C. The raw material used is a mixture of Pb(DPM)₂, Zr(DPM)₄ or Ti(i-PrO)₂(DPM)₂, and THF. The pressure in the deposition chamber ranges from about 66.65 to about 666.5 Pa (from about 0.5 to about 5 Torr).

The PLZT film is formed by a CVD process under the following conditions: The temperature of the silicon substrate 1 ranges from 300 to 600° C. The raw material used is a mixture of Pb(DPM)₂, La(DPM)₂, Zr(DPM)₄ or Ti(i-PrO)₂(DPM)₂, and THF. The pressure in the deposition chamber ranges from about 66.65 to about 666.5 Pa (from about 0.5 to about 5 Torr).

The Ta₂O₅ film is formed by a CVD process under the following conditions: The temperature of the silicon substrate 1 ranges from 600 to 750° C. The raw material used is Ta₂(OC₂H₅)₅. The pressure in the deposition chamber ranges from about 13.33 to about 666.5 Pa (from about 0.1 to about 5 Torr).

The SBT film is formed by a CVD process under the following conditions: The temperature of the silicon substrate 1 ranges from 300 to 550° C. The raw material used is a mixture of [Ta(OC₂H₅)₆]₂ and Bi(CH₃)₃. The pressure in the deposition chamber ranges from about 13.33 to about 666.5 Pa (from about 0.1 to about 5 Torr).

Although an example of the formation of the dielectric film 81 by the sputtering process is described above, the technique of forming the dielectric film 81 is not limited to the sputtering process so far as a physical deposition process, i.e., a PVD process is used.

For instance, an ion beam sputtering process may be used in which accelerated noble gas ions are directed onto the target material to sputter the target material.

Alternatively, a laser ablation process may be used in which a laser beam is directed onto the target material to produce a local high-temperature part, thereby vaporizing the target material for film deposition.

Alternatively, a molecular beam epitaxy (MBE) process may be used in which a raw material is vaporized in a ultrahigh vacuum and is deposited on a heated substrate.

An example of the formation of the dielectric film 82 by the CVD process, particularly a MOCVD (metal organic chemical vapor deposition) process in which film deposition is accomplished by vapor deposition using an organic compound of metal as a raw material, is described above. However, the technique of forming the dielectric film 82 is not limited to the CVD process so far as a chemical deposition process is used.

For example, a sol-gel method may be used in which an organic compound of metal dissolved in a solvent is applied onto the substrate, dried, and sintered.

Alternatively, a metal organic deposition (MOD) process may be used in which an organic compound of metal dissolved in a solvent is sprayed onto the substrate, dried, and sintered.

<B. Second Preferred Embodiment>

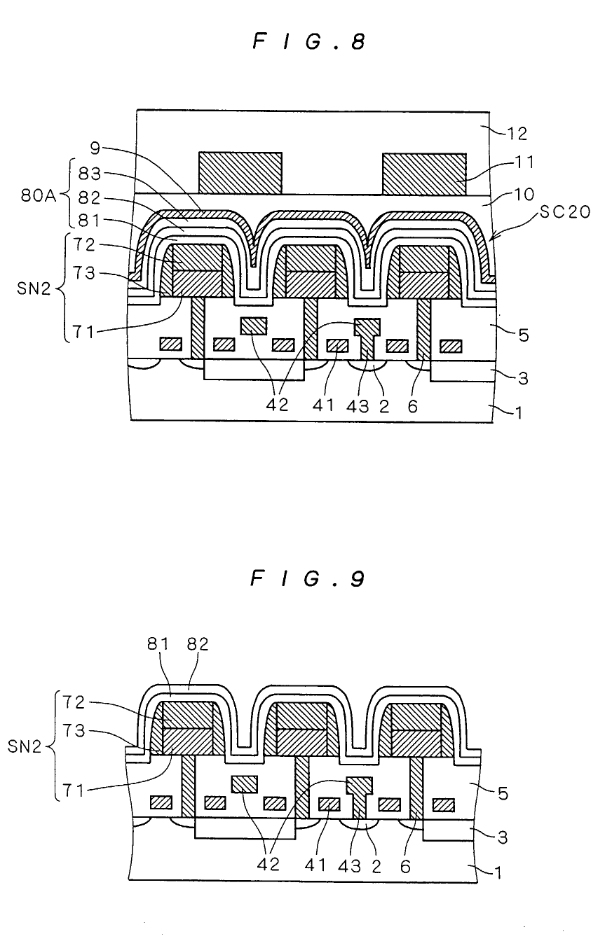

FIG. 8 shows a cross-sectional structure of a memory cell portion of a DRAM 200 according to a second preferred embodiment of the present invention. In FIG. 8, components identical with those of the DRAM 100 shown in FIG. 1 are designated by like reference numerals and characters, and are not described in the second preferred embodiment.

<B-1. Device Construction>

With reference to FIG. 8, the dielectric film 81 (the first dielectric film) formed of BST by the sputtering process is entirely provided to cover upper part of the plurality of storage node electrodes SN2 (the lower electrode).

The dielectric film 82 (the second dielectric film) formed of BST by the CVD process is entirely provided to cover the dielectric film 81. A dielectric film 83 (a third dielectric film) formed of BST by a sputtering process is entirely provided to cover the dielectric film 82. The dielectric films 81 to 83 constitute a dielectric layer 80A.

A conductive layer made of platinum is entirely provided to cover the dielectric film 83, constituting the counter electrode (referred to as a cell plate) 9 (the upper electrode) to the storage node electrodes SN2.

Each of the storage node electrodes SN2, the dielectric films 81 to 83, and the cell plate 9 constitute a stacked capacitor SC20.

The interlayer insulation film 10 covers the stacked capacitors SC20, and the metal interconnect layer 11 is provided on the interlayer insulation film 10. The passivation film 12 covers the metal interconnect layer 11. The DRAM 200 is thus constructed.

<B-2. Manufacturing Method>

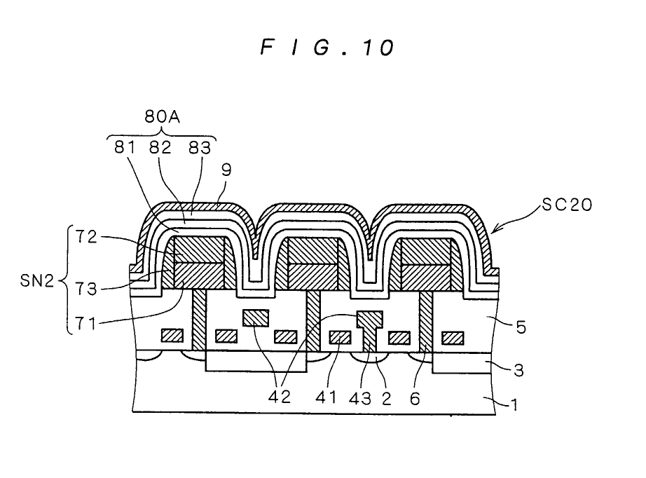

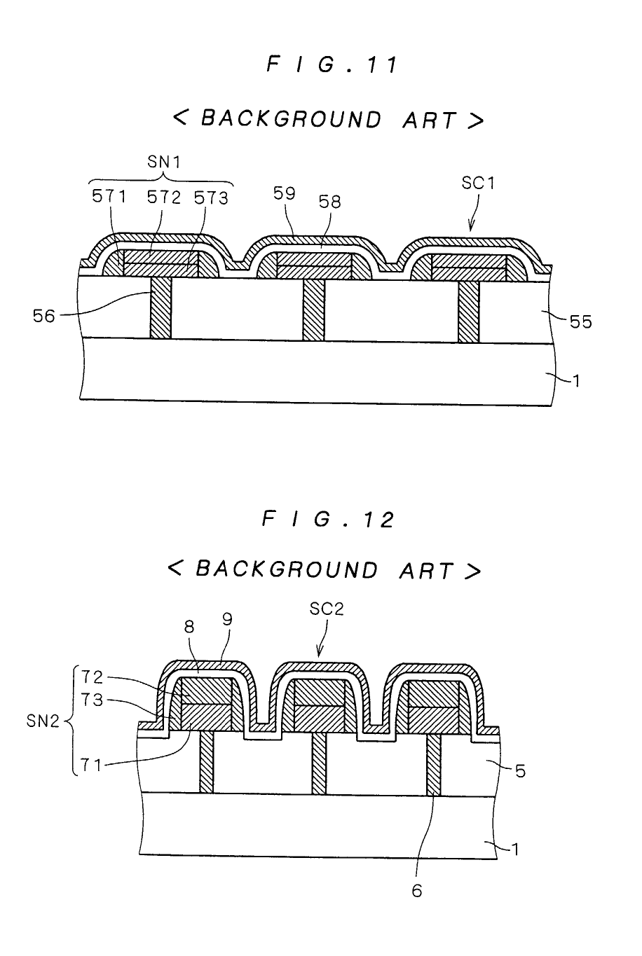

A method of manufacturing the DRAM 200 will be discussed with reference to FIGS. 9 and 10. The manufacturing steps performed until the storage node electrodes SN2 are formed in the second preferred embodiment are similar to those described with reference to FIGS. 2 through 6, and are not described in the second preferred embodiment. The manufacturing steps of the components identical with those of the DRAM 100 of the first preferred embodiment will be briefly described.

In the step shown in FIG. 9, a BST film is entirely formed by a sputtering process to cover the storage node electrodes SN2, thereby forming the dielectric film 81.

Then, a BST film is formed by a CVD process to entirely cover the dielectric film 81, thereby forming the dielectric film 82.

Next, in the step shown in FIG. 10, a BST film is entirely formed by a sputtering process to cover the dielectric film 82, thereby forming the dielectric film 83.

The dielectric film 83 is formed under the following conditions: A technique of sputtering a target material using ions or atoms produced by a plasma generated by high-frequency discharge is used. The temperature of the silicon substrate 1 ranges from 200 to 600° C. Argon gas (Ar) and oxygen (O₂) at a 1:0 or 1:1 ratio are introduced into a deposition chamber. The pressure in the deposition chamber is about 0.1 Pa. High-frequency power for input to the target material is about 1 kW. The thickness of the dielectric film 83 ranges from 5 to 30 nm. The conditions of the target material and the like are similar to those for the dielectric film 81.

Then, a platinum layer is formed by a sputtering process to entirely cover the dielectric film 83, thereby forming the cell plate 9 (the upper electrode). The cell plate 9 has a thickness of about 60 nm.

Subsequently, the interlayer insulation film 10 is formed to completely cover the stacked capacitors SC20. Then, the metal interconnect layer 11 is formed on the interlayer insulation film 10, and the passivation film 12 is formed to cover the metal interconnect layer 11.

Finally, a hydrogen anneal is performed in an atmosphere of hydrogen at a temperature of 400° C. for 20 minutes to recover damages caused in the course of the manufacture. Thus, the DRAM 200 shown in FIG. 8 is completed.

<B-3. Function and Effect>

The DRAM 200 described above comprises the dielectric film 83 which further covers the dielectric film 82.

The dielectric film 82 formed by the CVD process contains impurities such as CO₂ and H₂O, and is prone to adsorb such molecules in the atmosphere. Thus, when the cell plate 9 is formed directly on the dielectric film 82, a large number of crystal defects might be produced at an interface between the dielectric film 82 and the cell plate 9, resulting in the increase in dielectric loss and the like.

However, covering the upper surface of the dielectric film 82 with the dielectric film 83 causes the cell plate 9 to provide an interface with the upper surface of the dielectric film 83 formed by the sputtering process and having good film quality, thereby avoiding the increase in dielectric loss.

The dielectric films 81 to 83 described above include a ferroelectric film, a high-dielectric film, and a dielectric film having the property of acting as a ferroelectric or high-dielectric film depending on conditions.

While the invention has been described in detail, the foregoing description is in all aspects illustrative and not restrictive. It is understood that numerous other modifications and variations can be devised without departing from the scope of the invention.

What is claimed is:

1. A semiconductor device comprising:
an underlying layer; and
a plurality of capacitors formed on said underlying layer, each of said plurality of capacitors including a lower electrode, a dielectric layer, and an upper electrode provided in opposed relation to said lower electrode with said dielectric layer therebetween,
said dielectric layer including
a first dielectric film provided to cover an upper part and a side surface of said lower electrode and an upper part of said underlying layer which lies between said plurality of capacitors, and
a second dielectric film provided to cover an upper part and a side surface of said first dielectric film which overlies said lower electrode, and an upper part of said first dielectric film which lies between said plurality of capacitors,
wherein said first and second dielectric films have a perovskite-type crystal structure, and have substantially the same lattice constant.

2. The semiconductor device according to claim 1,
wherein said first dielectric film contains at least one of an ion at a face-centered position and an ion at a body-centered position of said perovskite-type crystal structure of said second dielectric film.

3. The semiconductor device according to claim 1,
wherein said first dielectric film is formed by a physical deposition process, and
wherein said second dielectric film is formed by a chemical deposition process.

4. The semiconductor device according to claim 3,
wherein said first dielectric film is formed by a sputtering process, and
wherein said second dielectric film is formed by a CVD process.

5. The semiconductor device according to claim 3,
wherein said dielectric layer further includes
a third dielectric film provided to cover an upper part and a side surface of said second dielectric film which overlies said lower electrode, and an upper part of said second dielectric film which lies between said plurality of capacitors.

6. The semiconductor device according to claim 5,
wherein said third dielectric film is formed by a physical deposition process.

7. A method of manufacturing a semiconductor device including a plurality of capacitors formed on an underlying layer, each of said plurality of capacitors including a lower electrode, a dielectric layer, and an upper electrode provided in opposed relation to said lower electrode with said dielectric layer therebetween, said method comprising the step of
forming said dielectric layer,
said step of forming said dielectric layer including the steps of:
(a) forming a first dielectric film by a physical deposition process to cover an upper part and a side surface of said lower electrode and an upper part of said underlying layer which lies between said plurality of capacitors, and
(b) forming a second dielectric film by a chemical deposition process by using a crystal of said first dielectric film as a seed to cover an upper part and a side surface of said first dielectric film which overlies said lower electrode, and an upper part of said first dielectric film which lies between said plurality of capacitors,
wherein said first and second dielectric films have a perovskite-type crystal structure, and have substantially the same lattice constant.

8. The method according to claim 7,
wherein said step (a) comprises the step of
forming said first dielectric film by a sputtering process; and
wherein said step (b) comprises the step of
forming said second dielectric film by a CVD process.

9. The method according to claim 7,
wherein said step of forming said dielectric layer further includes the step of
(c) forming a third dielectric film by a physical deposition process to cover an upper part and a side surface of said second dielectric film which overlies said lower electrode, and an upper part of said second dielectric film which lies between said plurality of capacitors, said step (c) being performed after said step (b).
